(19) United States
(12) Patent Application Publication
(10) Pub. No.: US 2025/0199041 A1
(43) Pub. Date: Jun. 19, 2025

(54) CAPACITIVE SENSOR AND METHOD FOR OPERATING A CAPACITIVE SENSOR

(71) Applicant: Robert Bosch GmbH, Stuttgart (DE)

(72) Inventors: David Slogsnat, Tuebingen (DE); Domenico Tangredi, Milano (IT); Massimiliano Musazzi, Como (IT)

(21) Appl. No.: 18/720,249

(22) PCT Filed: Jan. 30, 2023
(86) PCT No.: PCT/EP2023/052182

§ 371 Date: Jun. 14, 2024

(30) Foreign Application Priority Data
Mar. 8, 2022 (DE) 10 2022 202 297.1

(51) Int. Cl. G01R 27/26; B81B 7/02

(52) U.S. Cl. CPC G01R 27/2605; B81B 7/02; B81B 2201/0264

(57) ABSTRACT

A capacitive sensor. The capacitive sensor includes: a MEMS element including a capacitive Wheatstone bridge circuit; and an ASIC element, wherein the ASIC element is designed to ascertain a measured value of at least one reference capacitance of the capacitive Wheatstone bridge circuit, wherein actuation signals for ascertaining the reference capacitance are applicable to a respective supply line of the capacitive Wheatstone bridge circuit, wherein the ASIC element is designed to read and evaluate the measured values of the reference capacitances, wherein a resistance value of at least one short-circuit resistance of the capacitive sensor is ascertainable from the values of the reference capacitances.

### FIELD

The present invention relates to a capacitive sensor. The present invention also relates to a method for operating a capacitive sensor. The present invention furthermore relates to a computer program product.

### BACKGROUND INFORMATION

Pressure sensors are becoming increasingly popular in devices such as smartphones, smartwatches, fitness trackers and wearables, as well as in the IoT market. Use cases are not only limited to weather detection and altitude estimation but are also expanded by new use cases that come onto the market, such as the highly precise ground level detection for 911 emergency sites.

For reliable functionality, it is becoming increasingly important to ensure functionality over the entire service life. An important feature in this respect is the ability to detect malfunctions of the device by means of a self-test. Conventionally, pressure sensors are exposed to the environment and liquids may therefore come into contact with them. This can disadvantageously cause offsets in the pressure measurements due to the presence of mass in the form of the liquid, wherein the liquid may, for example, be in the form of water, oil, sweat, etc.

Self-tests for sensors in which excitation of a MEMS element is used to carry out a subsequent check of measured values are described in the related art.

U.S. Patent Application Publication No. US 2010/180687 A1 describes a pressure sensor with switchable sensor elements, in which reference elements are indirectly read in that these self-tests are switched between branches of a Wheatstone bridge.

### SUMMARY

It is an object of the present invention to provide an improved capacitive sensor.

According to a first aspect of the present invention, the object may be achieved with a capacitive sensor comprising:
a MEMS element comprising a Wheatstone bridge circuit; and
an ASIC element, wherein the ASIC element is designed to ascertain a measured value of at least one reference capacitance of the capacitive Wheatstone bridge circuit, wherein actuation signals for ascertaining the reference capacitance are appliable to respective a supply line of the capacitive Wheatstone bridge circuit, wherein the ASIC element is designed to read and evaluate the measured values of the reference capacitances, wherein a resistance value of at least one short-circuit resistance of the capacitive sensor is ascertainable from the values of the reference capacitances.

The method according to an example embodiment of the present invention exploits the fact that a measured capacitance value is distorted by a short-circuit resistance. The value of the measured reference capacitances is not at all of interest, but the values of the reference capacitors are used to some extent as indicators in order to detect short circuits, which may be present for production-related reasons. Evaluation software may, for example, be hardwired in an ASIC and is used to perform a self-test of the capacitive sensor.

Advantageously, according to an example embodiment of the present invention, a capacitive sensor with which a self-test can be carried out in a simple manner is provided in this way. Advantageously, this does not require any additional dedicated detection component, because the capacitive pressure sensor can be used with already existing hardware components. As a result, it can thereby be advantageously determined whether a measurement operation with the capacitive sensor may be incorrect.

According to a second aspect of the present invention, the object may achieved with a method for operating a capacitive sensor, comprising the steps of:
applying an actuation signal to a supply line of a capacitive Wheatstone bridge circuit;
ascertaining capacitance values of reference capacitances of the capacitive Wheatstone bridge circuit;
evaluating the ascertained capacitance values of reference capacitances of the capacitive Wheatstone bridge circuit; and
ascertaining at least one short-circuit resistance from the evaluated capacitance values of the reference capacitances on the basis of a comparison to a defined reference value.

The method can be used in manufacturing or in the field, wherein, in the event of a fault, the sensor (e.g., a crash sensor in the automotive field) is replaced in order thereby to avoid consequential damages.

According to a third aspect of the present invention, the object may be achieved with a computer program product comprising program code means configured to carry out the proposed method when it runs on a proposed capacitive sensor or is stored on a computer-readable data carrier.

Advantageous example embodiments and developments of the capacitive sensor according to the present invention and of the method according to the present invention are disclosed herein.

Advantageous developments of the capacitive sensor provide that a first short-circuit resistance between a first supply line of the capacitive Wheatstone bridge circuit and ground potential, a second short-circuit resistance between a second supply line of the capacitive Wheatstone bridge circuit and ground potential, and a third short-circuit resistance between the first supply line and the second supply line of the capacitive Wheatstone bridge circuit are ascertainable.

A further advantageous development of the capacitive sensor of the present invention provides that a serial resistance in the first supply line and/or the second supply line is furthermore also ascertainable.

A further advantageous development of the capacitive pressure sensor of the present invention provides that an actuation signal for actuating measurement capacitances is generable by means of the ASIC element. This can advantageously minimize a circuit technology effort.

A further advantageous development of the capacitive sensor of the present invention provides that a defined reference value of a relation between the ascertained reference capacitances is used to ascertain the at least one short-circuit resistance (R_{KS}).

Further advantageous developments of the capacitive sensor of the present invention provide that the at least one short-circuit resistance is ascertainable in a range between approximately 100 kΩ and approximately 1 MΩ.

The present invention is described in detail below with further features and advantages on the basis of several figures. The figures are primarily intended to illustrate main principles of the present invention.

Disclosed method features of the present invention result analogously from corresponding disclosed device features of the present invention, and vice versa. This means in particular that features, technical advantages and embodiments relating to the capacitive sensor of the present invention result analogously from corresponding embodiments, features and advantages relating to the method for operating a capacitive sensor according to the present invention, and vice versa.

### BRIEF DESCRIPTION OF THE DRAWINGS

FIG. 1 shows a perspective view of an example embodiment of a proposed capacitive sensor according to the present invention.

FIG. 2 shows a cross-sectional view through the embodiment of the proposed capacitive sensor of FIG. 1.

FIG. 3 shows a basic block diagram of a conventional capacitive sensor in a normal operation.

FIGS. 4 and 5 show basic circuit diagrams of the proposed capacitive sensor in a test operation, according to an example embodiment of the present invention.

FIG. 6 shows a circuit diagram with various resistances, which can be ascertained with the proposed method according to an example embodiment of the present invention.

FIG. 7 shows a time flowchart with a basic flow of the proposed method for operating a capacitive sensor according to an example embodiment of the present invention.

FIG. 8 shows a time flowchart with a basic flow of the proposed method for operating a capacitive sensor, according to an example embodiment of the present invention.

### DETAILED DESCRIPTION OF EXAMPLE EMBODIMENTS

Proposed is a capacitive sensor, which may, for example, be designed as a barometric capacitive pressure sensor. In such a capacitive sensor, pressure is sensed by means of a MEMS element, in which both variable capacitances (pressure measuring elements) and fixed reference capacitances are installed, and which are arranged in a capacitive Wheatstone bridge circuit. While some faults and failures of the capacitive sensor can be detected during the measurement of the entire Wheatstone bridge, individual capacitance measurements are proposed with the proposed capacitive sensor in order to find more potential problems.

With the proposed capacitive sensor, dedicated elements or signal processing chains are advantageously not necessary; a proposed test process can, for example, be realized with a specific configuration of the ASIC element.

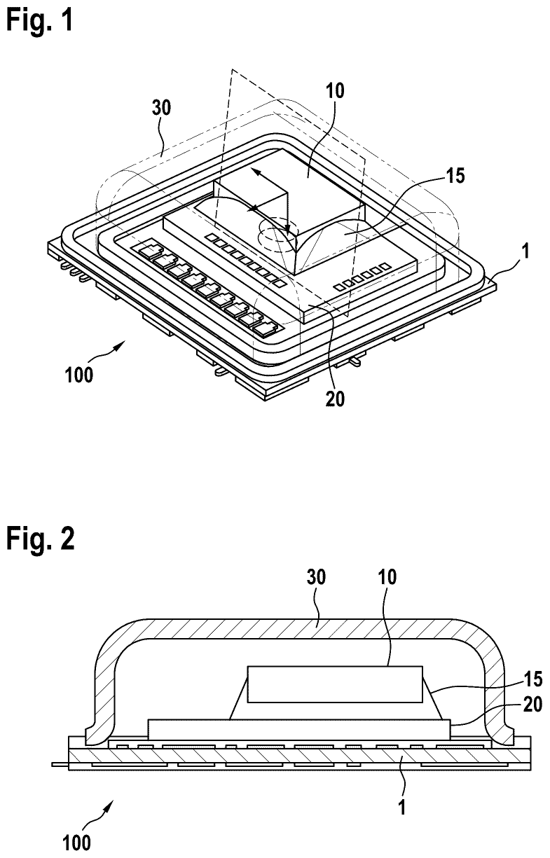

In the embodiment of the proposed capacitive sensor 100 of FIG. 1, it can be seen that a MEMS element 10 is arranged on an ASIC element 20. A damping element 15, e.g., in the form of Semicosil, is preferably arranged between the MEMS element 10 and the ASIC element 20. The capacitive sensor 100 and the ASIC element 20 are covered by a cap element 30 (e.g., metal lid) and thereby protected. Also possible but not shown in the figures are other embodiments of the capacitive sensor 100 with other layers of MEMS element 10 and ASIC element 20.

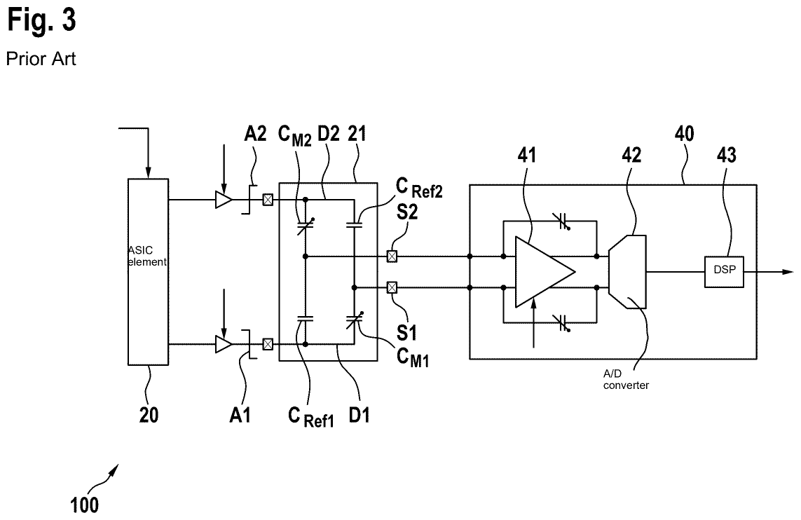

FIG. 2 shows a cross-sectional view of the capacitive sensor 100 of FIG. 1.

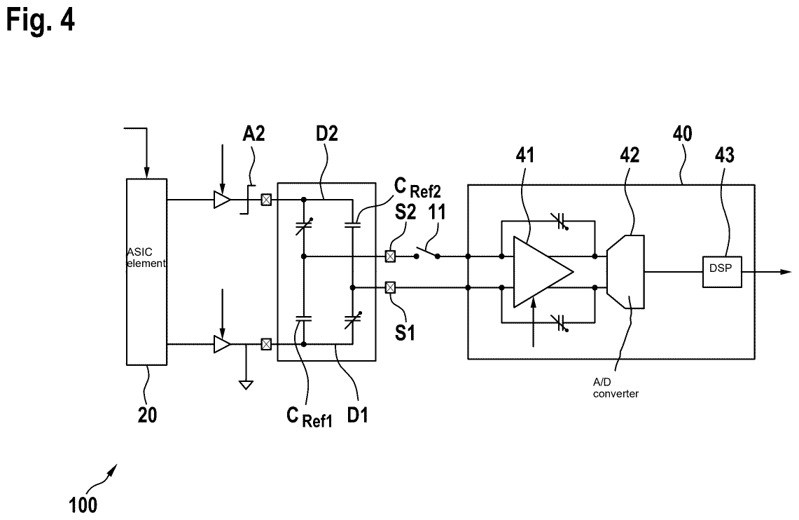

Barometric pressure is sensed by means of the MEMS element 10, in which a full capacitive Wheatstone bridge circuit 21 is implemented, as shown in FIG. 3. Two measuring elements of the capacitive bridge circuit 21 are variable measurement capacitances C_{M1}, C_{M2} and are provided for pressure measurement. The other two elements represent capacitances with a fixed capacitance value, which are used in the proposed capacitive sensor 100 as reference capacitances C_{Ref1}, C_{Ref2}.

For the purposes of electrical contacting, bonding wires (not shown) are used, in particular for the electrical contacting between the ASIC element 20 and the substrate 1 (printed circuit board) arranged under it, and between the ASIC element 20 and the MEMS element 10. Furthermore, the bond wires can also be used to electrically connect the ASIC element 20 to the capacitive bridge circuit 21.

The capacitive bridge circuit 21 is actuated by electrical actuation signals A1, A2, which may, for example, be square-wave signals with frequencies of approximately 30 kHz to approximately 70 kHz. A first electrical actuation signal A1 is applied to a first supply line D1, and a second electrical measurement signal M2 is applied to a second supply line D2 of the capacitive bridge circuit 21.

FIG. 3 shows a conventional capacitive sensor 100 with the capacitive bridge circuit 21 in a “normal operation,” in which all bridge capacitances are ascertained for the purpose of a barometric pressure measurement. A first measurement capacitance C_{M1} can be seen, which is actuated by an actuation element (e.g., ASIC element 20) with the first actuation signal A1. In this case, a capacitance value of the first measuring element C_{M1} is ascertained, e.g., through a calculation by means of a downstream evaluation element 40 (e.g., microcomputer) of the ASIC element 20.

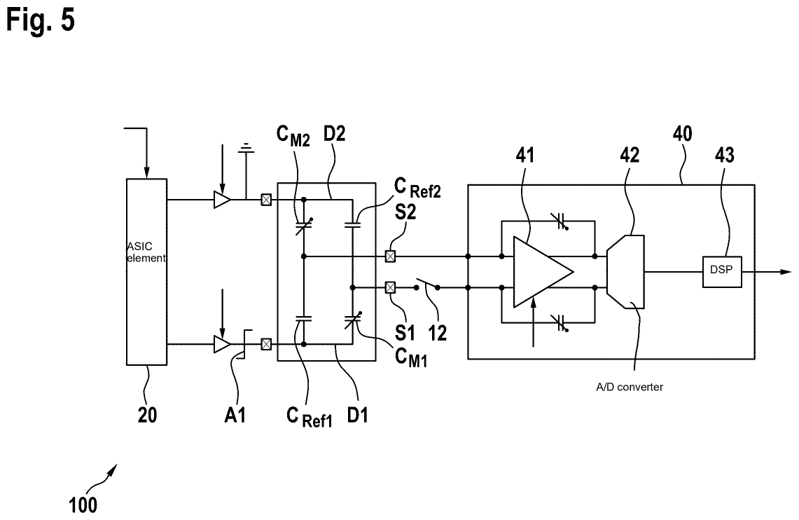

FIG. 4 shows an embodiment of the proposed capacitive sensor 100 in a test mode, in which only an individual reference capacitance C_{Ref1}, C_{Ref2} is in each case ascertained one after the other, wherein only the second reference capacitance C_{Ref2} is ascertained in this case. For this purpose, a second actuation signal A2 is applied to the second supply line D2 and a measurement signal of the second reference capacitance C_{Ref2} is read at a terminal S1, wherein a terminal S2 is disconnected from the evaluation element 40 as a result of an open switch element 11. The first supply line D1 is connected to ground potential GND during the measurement operation.

The evaluation element 40 comprises an amplification element 41 (e.g., low noise amplifier), a downstream A/D converter 42, and a downstream digital signal processor 43. The mode of operation of such an evaluation element 40 is conventional and is therefore not explained in more detail here.

FIG. 5 likewise shows the proposed capacitive sensor 100 in test mode, wherein only the first reference capacitance C_{Ref1} is ascertained in this case. For this purpose, a first actuation signal A1 is applied to the first supply line D1 and a measurement signal of the first reference capacitance C_{Ref1} is read at a terminal S2, wherein a terminal S1 is disconnected from the evaluation element 40 as a result of an open switch element 12. The second supply line D2 is connected to ground potential GND in this case. The measurement signal is supplied to the evaluation element 40 for evaluation. The second supply line D2 is connected to ground potential GND during the measurement operation.

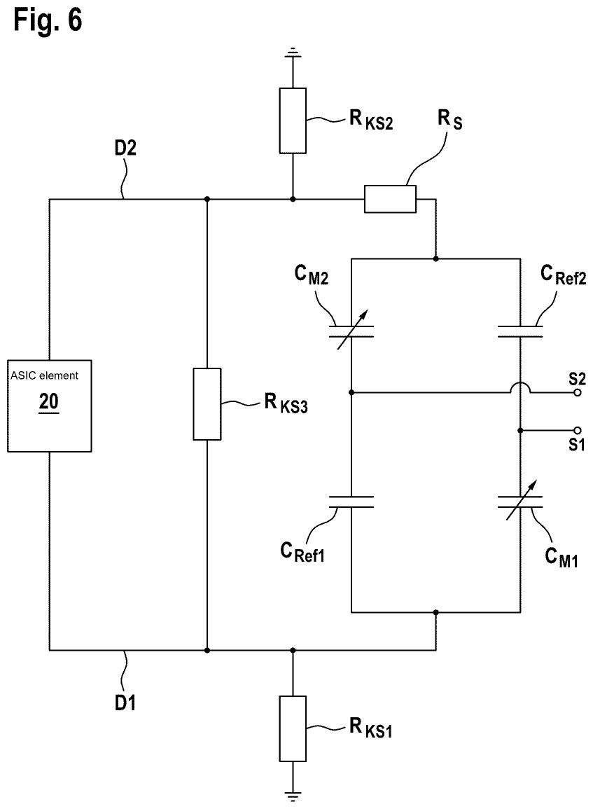

FIG. 6 shows the capacitive Wheatstone bridge circuit 21 with potentially low-ohmic short-circuit resistances R_{KS1} . . . . R_{KSn}, which are ascertainable with the proposed method. They can be either between the first supply line D1 and ground potential GND and/or between the second supply line D2 and ground potential GND and/or between the first supply line D1 and the second supply line D2. Resistance values of the short-circuit resistances may, for example, be between approximately 100 kΩ and approximately 1 MΩ, but other ohmic resistance values of the low-ohmic short-circuit resistances R_{KS} are also possible.

Some failures of the system can be detected by directly measuring the capacitive Wheatstone bridge circuit 21. Others cannot, such as short circuits in the drive part of the capacitive Wheatstone bridge circuit 21. These short circuits can considerably reduce the bandwidth of the actuation signal, which can lead to an excitation of the resonance modes of the capacitive sensor 100 and can prolong the settling time of the system. This can disadvantageously lead to offset errors and/or an increase in noise, for example. Since the occurrence of such effects can also depend on the temperature and the pressure, they can only be detected with greater effort under some circumstances.

With the proposed method, such short circuits can be easily detected by individually measuring the reference capacitances C_{Ref1}, C_{Ref2}.

The short circuits according to FIG. 4 provide different measured values for the two reference capacitances C_{Ref1}/C_{Ref2}.

For a short circuit between the first supply line D1 (or the second supply line D2) to ground potential GND, the measured value of the corresponding reference capacitance C_{Ref1} (or C_{Ref2}) is reduced by a reduction factor R according to the following formula:

$$R = 1 / 2 ⋆ {R}_{S} / ( {R}_{S} + {R}_{KS} ) \qquad ( 1 )$$

with:
R_{KS} . . . ohmic short-circuit resistance
R_{S} . . . ohmic series resistance between the driving circuit and the first or second supply line D1, D2

The capacitances and the series resistances R_{S} are typically matched with one another due to the production. Thus, if a difference between the measured values exceeds a particular reference value, it can be assumed that one or more electrical short-circuits are present.

In a typical application of the proposed capacitive sensor 100, it is therefore sufficient to ascertain and check a difference between the reference capacitances C_{Ref1}, C_{Ref2}. This can take place, for example, by reading the two reference capacitances C_{Ref1}, C_{Ref2}, wherein a calculation of the absolute or relative difference between the two reference capacitances C_{Ref1}, C_{Ref2} and a comparison to a predefined reference value R_{W} are carried out.

In the event that the predefined reference value R_{W} is exceeded, a fault is detected (at least one short circuit is present). If the reference value R_{W} is fallen below, the capacitive sensor 100 is identified as a good part (no short circuit is present).

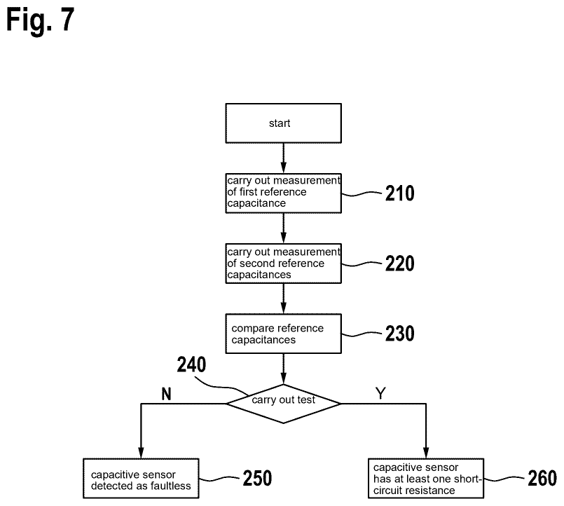

FIG. 7 shows a flow chart of the failure test for short circuits between the first supply line D1 or the second supply line D2 and ground potential GND:

In a step 210, a measurement of the first reference capacitance C_{Ref1} is carried out.

In a step 220, a measurement of the second reference capacitance C_{Ref2} is carried out.

In a step 230, the reference capacitances C_{Ref1}, C_{Ref2} are compared to one another.

In a step 240, a test is carried out as to whether a result of the following formula:

$${C}_{Ref 1} - {C}_{Ref 2} / {C}_{Ref 1} \qquad ( 1 )$$

is greater than a predefined reference value R_{W}.

If this is not the case, it is detected in a step 250 that the capacitive sensor 100 is faultless.

If this is the case, it is detected in a step 260 that the capacitive sensor 100 has at least one short-circuit resistance R_{KS}.

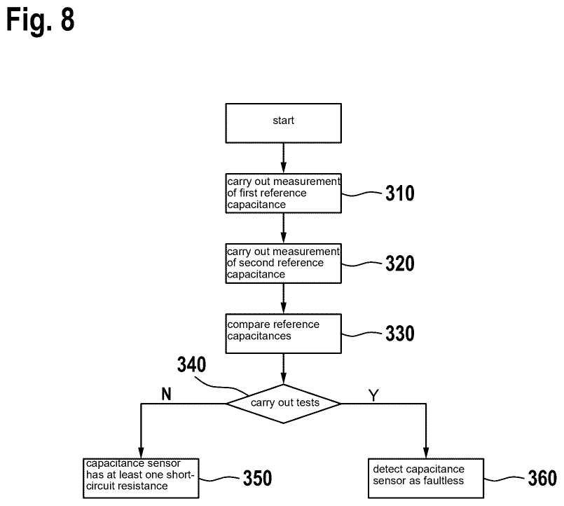

FIG. 8 shows a flow of a method for ascertaining a short circuit between the first and second supply lines D1, D2.

For ascertaining a short circuit between the first supply line D1 and the second supply line D2, the measured value of both measurement capacitances C_{M1}/C_{M2} is reduced by a reduction factor R as follows:

$$R = {R}_{S} / ( {R}_{S} + {R}_{KS} / 2 ) \qquad ( 2 )$$

In this case, the short-circuit resistance can be ascertained by directly comparing one and/or both values to a reference value R_{W}. This reference value R_{W} can be a fixed value for the capacitive sensor 100, wherein the reference value R_{W} is preferably determined for individual production batches of the capacitive sensor 100.

The stated formulas (1), (2) are merely exemplary and can be replaced and/or supplemented by other formulas.

In a step 310, a measurement of the first reference capacitance C_{Ref1} is carried out.

In a step 320, a measurement of the second reference capacitance C_{Ref2} is carried out.

In a step 330, the reference capacitances C_{Ref1}, C_{Ref2} are compared to one another.

In a step 240, a test is carried out as to whether all conditions of the following formula are fulfilled:

C_{Ref1}<upper threshold value AND

C_{Ref1}>lower threshold value AND

C_{Ref2}<upper threshold value AND

C_{Ref2}>lower threshold value

If all four conditions are fulfilled, it is determined in a step 360 that the capacitive sensor 100 is faultless.

If the four conditions are not fulfilled, it is detected in a step 350 that the capacitive sensor 100 has at least one short-circuit resistance R_{KS}.

Advantageously, the proposed method can be used in a final test of a production process of capacitive pressure sensors as well as in normal operation of such sensors but can also be used for other capacitive sensors.

One example of generating the fixed value for a production batch would, for example, be ascertaining a distribution of the reference capacitances C_{Ref1}, C_{Ref2} and defining a limit value at a value so that a particular distribution of the reference capacitances is identified as a good part. For example, this could be a 6 sigma normal distribution.

The proposed method can, for example, be performed in the form of a self-test during the production tests. It could also be performed later in the field. In this case, the comparison value/threshold value can be stored in a non-volatile memory in the production unit.

The proposed method can, for example, be used as a test method within the scope of a production test in order to eliminate faulty sensors. Additionally, it can optionally also be used later in the product as a test in order to detect faults during the service life of the capacitive sensor 100.

The explained detection principle can also be used for embodiments of the capacitive sensor 100 that are different from that explained above, e.g., for capacitive sensors 100 that are characterized by a different number of pads and with a different position of the wire bonds between the bridge circuit 21 of the MEMS element 10 and the ASIC element 20.

In all variants explained, the electrical actuation signal A1, A1 can, for example, be designed as an electrical current signal, voltage signal or charge signal, whereby a capacitance value of the measurement capacitance CM1, CM2 can be ascertained. A signal form of the actuation signal A can, for example, be square-wave, sinusoidal, etc.

The proposed method can preferably be designed as software executed at least partially on the ASIC element 20 or at least partially externally thereof, whereby simple adaptability of the method is supported. Alternatively, the proposed method can be realized at least partially or also entirely in hardware.

Advantageously, the proposed method can be realized as a computer program that runs on the ASIC element 20 of the capacitive sensor 100 or is stored on a computer-readable data carrier.

In summary, the present invention proposes a capacitive sensor and a method for operating a capacitive pressure sensor, with which a self-test is easily possible, whereby advantageously a status of the capacitive sensor and an admissibility of measurement operations can be assessed.

The person skilled in the art will modify and/or combine the features of the present invention in a suitable manner without departing from the core of the present invention.

1-13. (canceled)

14. A capacitive sensor, comprising:
a MEMS element including a capacitive Wheatstone bridge circuit; and
an ASIC element, wherein the ASIC element is configured to ascertain measured values of at least one reference capacitance of the capacitive Wheatstone bridge circuit, wherein actuation signals for ascertaining the at least one reference capacitance are appliable to a respective supply line of the capacitive Wheatstone bridge circuit, wherein the ASIC element is configured to read and evaluate the measured values of the at least one reference capacitance, wherein a resistance value of at least one short-circuit resistance of the capacitive sensor is ascertainable from the measured values of the at least one reference capacitance.

15. The capacitive sensor according to claim 14, wherein a first short-circuit resistance between a first supply line of the capacitive Wheatstone bridge circuit and ground potential, a second short-circuit resistance between a second supply line of the capacitive Wheatstone bridge circuit and ground potential, and a third short-circuit resistance between the first supply line and the second supply line of the capacitive Wheatstone bridge circuit are ascertainable.

16. The capacitive sensor according to claim 14, wherein a serial resistance is ascertainable in the first supply line and/or the second supply line.

17. The capacitive sensor according to claim 14, wherein an actuation signal for actuating measurement capacitances of the capacitive Wheatstone bridge circuit is generatable using the ASIC element.

18. The capacitive sensor according to claim 14, wherein the at least one reference capacitance includes a plurality of reference capacitances, and wherein a defined reference value of a relation between the ascertained reference capacitances is used to ascertain the at least one short-circuit resistance.

19. The capacitive sensor according to claim 14, wherein the at least one short-circuit resistance is ascertainable in a range between approximately 100 kΩ and approximately 1 MΩ.

20. The capacitive sensor according to claim 15, wherein, for ascertaining a second reference capacitance, a second actuation signal is appliable to the second supply line and a measurement signal of the second reference capacitance is readable at a first terminal, wherein a second terminal is disconnected from an evaluation element as a result of an open switch element and the first supply line is connectable to ground potential during a measurement operation; and wherein, for ascertaining a first reference capacitance, the second actuation signal is appliable to the first supply line and a measurement signal of the first reference capacitance is readable at the second terminal, wherein a first terminal is disconnected from the evaluation element as a result of an open switch element and the second supply line is connectable to ground potential during the measurement operation.

21. A method for operating a capacitive sensor, comprising the following steps:
applying an actuation signal to a supply line of a capacitive Wheatstone bridge circuit;
ascertaining capacitance values of reference capacitances of the capacitive Wheatstone bridge circuit;
evaluating the ascertained capacitance values of reference capacitances of the capacitive Wheatstone bridge circuit; and
ascertaining at least one short-circuit resistance from the evaluated capacitance values of the reference capacitances based on a comparison to a defined reference value.

22. The method according to claim 21, wherein a value of a first short-circuit resistance between a first supply line of the capacitive Wheatstone bridge and ground potential and/or a value of a second short-circuit resistance between a second supply line of the capacitive Wheatstone bridge and ground potential and/or a value of a third short-circuit resistance between the first and the second supply line is ascertained.

23. The method according to claim 22, wherein a value of a series resistance in the first supply line and/or the second supply line is ascertained.

24. The method according to claim 21, wherein a 6 sigma distribution is used to decide whether the capacitive sensor is good or bad.

25. The method according to claim 21, wherein the method is carried out at defined time points or cyclically.

26. A non-transitory computer-readable data carrier on which is stored a computer program with program code for operating a capacitive sensor, the program code, when executed by a computer, causing the computer to perform the following steps:
applying an actuation signal to a supply line of a capacitive Wheatstone bridge circuit;
ascertaining capacitance values of reference capacitances of the capacitive Wheatstone bridge circuit;
evaluating the ascertained capacitance values of reference capacitances of the capacitive Wheatstone bridge circuit; and
ascertaining at least one short-circuit resistance from the evaluated capacitance values of the reference capacitances based on a comparison to a defined reference value.
